(19) United States
(12) Patent Application Publication
(10) Pub. No.: US 2015/0092360 A1
(43) Pub. Date: Apr. 2, 2015

(54) BATTERY OVERMOLDING

(71) Applicant: NIKE, Inc, Beaverton, OR (US)

(72) Inventors: Martine Stillman, Seattle, WA (US); Dane Weitmann, Seattle, WA (US)

(73) Assignee: NIKE, Inc., Beaverton, OR (US)

(21) Appl. No.: 14/043,512

(22) Filed: Oct. 1, 2013

(51) Int. Cl. B29C 45/14; H01M 2/02; H05K 1/18

(52) U.S. Cl. CPC B29C 45/14836; H05K 1/181; B29C 45/14819; H01M 2/0267; H05K 2201/05; H05K 2201/10037; H05K 2201/10977; B29C 2045/14844; B29K 2021/003
USPC 361/749; 264/135

(57) ABSTRACT

A portable electronic device commonly includes one or more batteries. Further, a portable electronic device may be manufactured using one or more overmolding techniques to achieve certain aesthetic and/or mechanical characteristics. Batteries within the portable electronic device may be overmolded by using a covering, wherein the covering includes a protective layer such that the batteries are not exposed to the high temperatures and high pressures associated with an overmolding process which may be in excess of temperature and pressure thresholds associated with the batteries.

### BACKGROUND

Batteries are commonly used as sources of stored electrical energy for a variety of portable electronic devices ranging from laptop computers, mobile telephones, portable music players, wristwatches, navigational devices, and athletic performance monitoring devices, among many others. Furthermore, positioning of one or more batteries within an electronic device may be an important consideration from the perspective of a product designer/engineer, wherein the positioning of one or more batteries may be based upon issues related to the functionality, the aesthetics of the product, and size constraints, which can be particularly important in designing compact electronic devices.

In some instances, it may be desirable to use one or more overmolding processes during manufacture of a product, wherein overmolding refers to one or more processes to mold one or more substances at high temperatures and/or high pressures onto an existing material, component, etc. Accordingly, an overmolding process may be selected for manufacture of a portable electronic device based on a finished appearance of an overmolded product, the functionality and mechanical characteristics of an overmolded product, space and size constraints, or the economics of using an overmolding process, instead of one or more alternative manufacturing processes, among others. However, the temperature and/or pressure used during an overmolding process may exceed one or more temperature and pressure tolerance limits associated with a battery to be used in a given portable electronic device. As such, overmolding may damage the battery, or render the battery completely inoperable. Accordingly, a need exists for systems and methods that provide enhanced options for overmolding of batteries in such devices, particularly devices having a small form factor, or otherwise constrained internal space.

The present systems and methods described herein are provided to address the problems discussed above, and other problems, and to provide advantages and aspects not provided by prior battery solutions. A full discussion of the features and advantages of the present systems and methods is deferred to the following detailed description, which proceeds with reference to the accompanying drawings.

### SUMMARY

The following presents a simplified summary of the present disclosure in order to provide a basic understanding of some aspects of the invention. This summary is not an extensive overview of the invention. It is not intended to identify key or critical elements of the invention or to delineate or limit the scope of the invention. The following summary merely presents some concepts of the invention in a simplified form as a prelude to the more detailed description provided below.

Aspects of the systems and methods described herein relate to a battery assembly. The battery assembly has a battery and an epoxy coating that at least partially covers the battery in order to resist the temperatures and pressures associated with an overmolding fabrication process that produces an overmolded structure to at least partially encapsulate the battery.

### BRIEF DESCRIPTION OF THE DRAWINGS

FIG. 1 depicts an athletic performance monitoring device in which certain embodiments may operate, with transparency to illustrate internal detail.

FIG. 2 depicts an embodiment of a battery configuration.

FIG. 3 schematically depicts a first stage of a battery overmolding process, utilizing the battery configuration of FIG. 2.

FIG. 4 schematically depicts an overmolded structure resulting from the overmolding process of FIG. 3.

FIGS. 5A-5C schematically depict cross-sectional diagrams of multiple stages of a battery overmolding process.

FIG. 6 schematically depicts a cross-sectional view of an alternative overmolded battery structure.

FIG. 7 schematically depicts a cross-sectional view of an alternative overmolded battery structure.

FIG. 8 schematically depicts another embodiment of a structure for protection of a battery during and overmolding process.

FIG. 9 schematically depicts an overmolded structure utilizing the structure of FIG. 8.

FIG. 10 schematically depicts another embodiment of a structure for protection of a battery during and overmolding process.

### DETAILED DESCRIPTION

In the following description, reference is made to the accompanying drawings, which form a portion hereof, and in which are shown by way of illustration various example devices, systems, and environments in which aspects of the invention may be practiced. When the same reference number appears in more than one drawing, that reference number is used consistently in this specification and the drawings refer to the same or similar part or object throughout. It is to be understood that other specific arrangements of parts, example devices, systems, environments or other objects may be utilized and structural and functional modifications may be made without departing from the scope of the present invention. Also, while the terms “top,” “bottom,” “front,” “back,” “side,” “rear,” and the like may be used in this specification to describe various example features and elements of the invention, these terms are used herein as a matter of convenience, e.g., based on the example orientations shown in the figures or the orientation during typical use. Additionally, the term “plurality,” as used herein, indicates any number greater than one, either disjunctively or conjunctively, as necessary, up to an infinite number. Nothing in this specification should be construed as requiring a specific three dimensional orientation of structures in order to fall within the scope of this invention. It is also understood that, as used herein, “providing” refers broadly to making an article available or accessible, including, e.g., for present and/or future actions to be performed on, by or in connection with, the article; for further clarity, such term as used herein, does not denote, connote or otherwise imply that any party is providing such article or that, in providing the article, any party will or has manufactured, produced, or supplied the article, or that the party providing the article has ownership or control of the article, unless and except if any such diction is explicitly set forth. Also, the reader is advised that the attached drawings are not necessarily drawn to scale.

In general, the present disclosure describes overmolding of a battery for use in a portable electronic device. In one implementation, the systems and methods described herein may be used to overmold a rechargeable lithium polymer (otherwise referred to as lithium-ion polymer, or polymer lithium ion) pillow-packed battery. However, one of ordinary skill will understand that the structures, configurations, systems and methods described herein may be employed using a variety of alternative battery types and configurations, including, but not limited to, alkaline, nickel cadmium, and nickel metal hydride batteries, among others. It is further understood that the structures, configurations, systems and methods described herein may be utilized or adapted for use in protecting a different type of electronic component during overmolding. In one implementation, such an electronic component may be a “circuit,” wherein a circuit may comprise one or more standard integrated circuits, application-specific integrated circuits (ASICs), field-programmable gate arrays (FPGAs), memory chips (such as ROM, RAM, and the like), or any electronic component that may be susceptible to malfunction and/or failure if exposed to the temperatures and pressures of an overmolding process.

The systems and methods described herein allow a battery to remain operational after an overmolding process has been performed to encapsulate the battery within one or more overmolded materials during manufacture or fabrication. Accordingly, the systems and methods described herein allow a battery to withstand high temperatures and pressures associated with an overmolding process, wherein an overmolding process may involve a temperature of 220° C. or greater, and pressures ranging from 20 MPa to 35 MPa (3000 psi to 5000 psi). Conventionally, a combination of one or more of such temperature or pressure levels may damage, or render inoperable, a battery. As a more specific example of such withstanding capability, the systems and methods described herein are configured to resist, or substantially resist, the pressure and temperature employed in an overmold process to mold a flowable substance over one or more components that include a battery. In this way, the systems and methods described herein may resist, or substantially resist, among others: ingress of a flowable substance associated with an overmold process into a battery housing structure, mechanical stress above a predetermined acceptable mechanical stress threshold for a battery, mechanical strain or deformation above a predetermined acceptable mechanical strain or deformation threshold for a battery, and/or an ambient, or a peak temperature above one or more temperature limits associated with operation or storage of a battery.

In general, the systems and methods described herein allow a flowable material/substance to be overmolded around a battery using, among others, polymer injection molding systems and methods, wherein a flowable substance that may be overmolded around a battery may include one or more of: thermoplastic polyurethane (TPU), thermoplastic elastomers (TPE), silicone materials, and other moldable elastomers, as well as other polymer resins such as nylon, acetal, polycarbonate, and the like. Other examples of such flowable substances for overmolding include other types of polymeric and/or composite materials. It is understood that such flowable substances may be selected for properties such as viscosity (e.g., at process temperature and pressure), strength, resilience, flexibility (e.g., following molding), bonding capability, compatibility with other materials, visual appearance, texture, or other aesthetic qualities, and/or other properties. To illustrate, in example overmolding processes, a flowable substance may be selected due to having a viscosity of about 10 Pa·s, or more; in other example overmolding processes, a flowable substance may be selected due to having a viscosity of about 1 Pa·s, or more; and in yet another example overmolding processes, a flowable substance may be selected even if having a viscosity of up to 200 Pa·s.

In the descriptions that follow, it will be understood that the example overmolding processes are described in a simplified manner, and that additional steps and parameters may be involved in any implemented overmolding process. Further, in the following exemplary embodiments in this disclosure, one or more overmolding processes may be described for overmolding a battery with a thermoplastic elastomer (TPE) flowable substance, however one of ordinary skill will recognize that the exemplary embodiments of this disclosure may be practiced using one or more of the alternative flowable overmolding substances previously described, or any material suitable for use in an overmolding process, or combinations thereof.

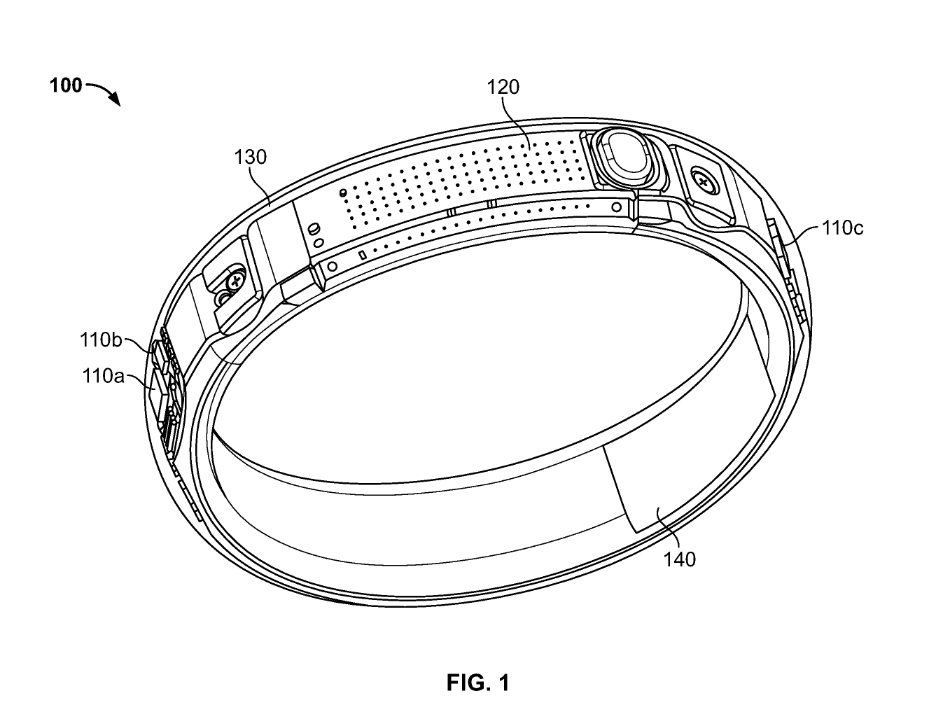

FIG. 1 depicts an athletic performance monitoring device 100 in which certain embodiments of the present disclosure may operate. In particular, the athletic performance monitoring device 100 may be worn on an appendage of an athlete, and execute one or more processes for monitoring one or more athletic activities being carried out by the athlete. The device 100 may include one or more electronic components 110a-110c, which may further include one or more sensors, such as accelerometers, gyroscopes, light sensors, microphones, GPS sensors, or magnetic field sensors, among others. In addition, the operation of the sensors may be controlled by one or more processors, wherein the one or more processors may be in communication with a form of volatile or persistent memory within device 100. Device 100 may calculate one or more metrics associated with one or more athletic activities, and communicate these metrics to a user via, among others, a display 120, which may include a visual and/or audio display. Accordingly, the one or more electronic components 110a-110c, in addition to display 120, may receive electrical energy from a battery 140 within device 100. In one implementation, device 100 may have an outer casing structure 130 formed at least partially, or wholly, from a thermoplastic elastomer. Furthermore, the outer casing structure 130 of device 100 may be formed by encapsulating one or more of electronic components 110a-110c, display 120, and battery 140 using one or more overmolding processes. In other implementations, the outer casing structure 130 may at least partially, or wholly, encase one or more electronic components, such as components 110a-110c, 212, 120, etc. It is understood that the device 100 may have a frame or other internal and/or external supporting structure for supporting the electronic components 110a-110c, the display 120, the battery 140, and/or other components of the device 100, as well as providing a base for supporting the overmolded outer casing structure 130.

In the descriptions that follow, references will be made to systems and methods for overmolding battery 140 of device 100, however one of ordinary skill will recognize that the systems and methods described herein may be generally practiced for overmolding a battery 140 for use in any electronic device, such as mobile telephones, portable music players, navigational devices, laptop computers, tablet computers, among others.

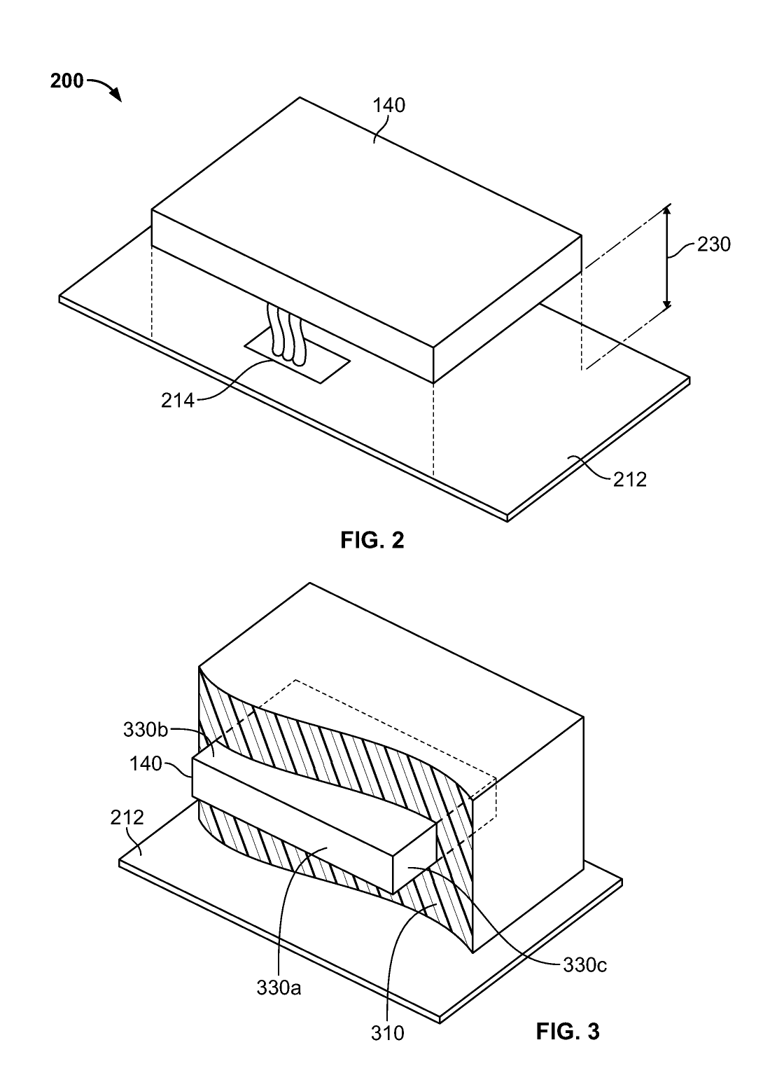

FIG. 2 depicts an embodiment of a battery configuration or assembly 200, which may be used in device 100 of FIG. 1. Configuration 200 includes battery 140 connected to a flexible printed circuit 212 via a wired connection 214. Battery 140 may be configured as a lithium polymer battery with a “pillow pack” structure. Such lithium polymer pillow pack batteries have associated tolerance limits for both pressure and temperature which may be unsuitable for conventional overmolding systems and methods. In particular, the temperature and pressure levels associated with an overmolding process, which may measure approximately 220° C. or greater, and approximately 20 MPa to 35 MPa or more, respectively, may exceed one or more of a temperature limit and a pressure limit associated with battery 140. However, it will be readily understood that battery 140 may be embodied using alternative battery technologies to the lithium polymer pillow pack battery 140 depicted herein. For example, battery 140 may be embodied using, among others, alkaline, nickel cadmium, and nickel metal hydride battery technologies. Furthermore, it will be understood that battery 140 may represent one or more connected chemical cells, and in an alternative embodiment of configuration 200, battery 140 may be a single cell.

Flexible printed circuit 212 may be configured with circuitry, including one or more discrete or integrated electronic components, for controlling the operation of battery 140. In this way, flexible printed circuit 212 may control the rate of discharge and/or recharge of electrical energy from/to battery 140, respectively. In another embodiment, the circuitry for controlling the rate of recharge and discharge of electrical energy to and from battery 140 may be integrated into a single battery structure 140. Accordingly, flexible printed circuit 212 may consume electrical energy from battery 140 to execute one or more processes associated with the operation of an electronic device, such as electronic device 100 in which battery 140 is embodied. The flexible printed circuit 212 may also be configured to control the operation of one or more additional components of the device 100, such as the components 110a-c, the display 120, and/or other components. As depicted in FIG. 2, the flexible printed circuit 212 is connected to battery 140 via wired connection 214, wherein wired connection 214 includes one or more conducting wires for communicating, among others, electrical energy for supplying power to one or more components of device 100. Wired connection 204 may further include one or more conducting wires for communicating information between battery 140 and flexible printed circuit 212, among others. Wired connection 214 may be embodied as a directly-soldered connection between battery 140 and flexible printed circuit 212, or may include a specially configured connectors or connector set for connection to the flexible printed circuit 212 in various embodiments. In yet another implementation, flexible printed circuit 212 may be embodied as a printed circuit board that is rigid, or any other type of structure known in the art for use to accommodate electrical circuitry and/or components. Furthermore, element 212 may be embodied as a one or more electronic components that do not include a printed circuit in other embodiments.

As depicted in FIG. 2, battery 140 is spaced apart from flexible printed circuit 212, and a spacing 230 exists between the two components. In one exemplary implementation, spacing 230 is approximately 2 mm. However, in other implementations, battery 140 and flexible printed circuit 212 may be substantially in contact with one another such that spacing 230 is approximately 0 mm. It will be readily apparent to one of skill that numerous alternative configurations to that of configuration 200 may be employed, without departing from the scope of the disclosures described herein. In this way, the relative positioning of battery 140, flexible printed circuit 212, and wired connection 214 may be different to that depicted in FIG. 2, and may be embodied in one of a plurality of alternative configurations known, or conceivable, to one of ordinary skill, and without departing from the spirit of the present disclosure.

It is further noted that while battery 140 is depicted with a schematic structure that is substantially rectangular (cuboidal) in shape, the systems and methods described herein may be practiced with batteries embodied with alternative shapes, including, but not limited to, curved battery shapes that substantially conform to the curved structure of the outer casing structure 130 from FIG. 1, or substantially cylindrical battery shapes.

The systems and methods described herein allow for overmolding of, among others, battery 140 by using an epoxy (epoxy resin) to cover the battery 140 prior to one or more overmolding processes being carried out. FIG. 3 schematically depicts a first stage of a battery overmolding process utilizing such an embodiment. In particular, FIG. 3 schematically depicts a cutaway view of battery 140 at least partially or completely covered by a protective polymer covering 310, which may be an epoxy coating, structure, or covering 310, in one embodiment. In general, the covering 310 may be formed of a polymer material (e.g., epoxy) that can be formed and molded from a flowable substance at temperatures and pressures that are within standard tolerances for a battery 140 as described herein, e.g., at relatively low pressure and at or near room temperature in one embodiment. Curing may be performed at temperatures of 80° F. or less, in one embodiment. In one implementation, covering 310 may be applied as a two-part epoxy resin that cures at or near room temperature, however those of skill will understand that alternative epoxies or other materials with similar properties may be used without departing from the scope of this disclosure.

In one implementation, covering 310 protects battery 140 from high levels of heat and pressure that may be associated with an overmolding process. Specifically, covering 310 provides thermal and pressure resistance such that the outer surface (330a-330c) of battery 140 does not experience temperature and/or pressure above one or more predetermined thresholds associated with battery 140. In fact, the temperatures and/or pressures experienced by the battery 140 may be significantly different than the temperatures and/or pressures involved experienced by the cover, such as at least a 40% reduction or at least a 50% reduction in some embodiments. For example, injection techniques may involve pressures up to 76 MPa (11,000 psi) and temperatures of around 200° C., and the battery 140 with the covering 310 as described above may only be subjected to temperatures of around 110° C. and 20 MPa-35 MPa (3000 psi to 5000 psi) in such a process. Further, the greatest temperature and/or pressure may be experienced by the thin side edges of the battery 140 in one embodiment, which are the areas of the battery 140 that generally can withstand the greatest temperature and pressure. It is understood that the configuration of the covering 310 and/or the mold cavity may affect the temperature and/or pressure experienced by the battery 140 and the portions of the battery 140 that experience the greatest temperature and/or pressure. Additionally, or alternatively, covering 310 functions to resist, or distribute, a pressure associated with an overmolding process such that the mechanical stress experienced by an outer surface (330a-330c) of battery 140 remains below one or more predetermined mechanical stress thresholds associated with battery 140.

As schematically depicted in FIG. 3, covering 310 completely covers battery 140, i.e., covers all outer surfaces 330a-330c of battery 140. In another embodiment, covering 310 may at least partially surround battery 140. For example, covering 310 may leave at least one outer surface (or portion thereof) of battery 140 uncovered. Additionally, as schematically depicted in FIG. 3, covering 310 partially covers flexible printed circuit 212. However, it will be readily apparent to one of ordinary skill that covering 310 may, at least partially or wholly, cover one or more components (such as components 212, 120, or 110a-110c) in addition to battery 140. In this way, covering 310 may offer protection to one or more components of device 100 during an overmolding process in addition to battery 140. In one embodiment, flexible printed circuit 212 may be connected to battery 140, e.g., by soldering, before covering 310 is applied to battery 140. In another embodiment, covering 310 may be applied to battery 140 before connection to flexible printed circuit 212, and/or the entire overmolding process may be conducted before connection of battery 140 to flexible printed circuit 212. Subsequent connection of circuit 212 to battery 140 may be performed by leaving at least a portion of wired connection 214 exposed, by forming (e.g., drilling) holes to reach battery 140, wireless power transmission, etc. In this configuration, additional leads for the battery 140 may be included, to provide increased options for connection in post-processing.

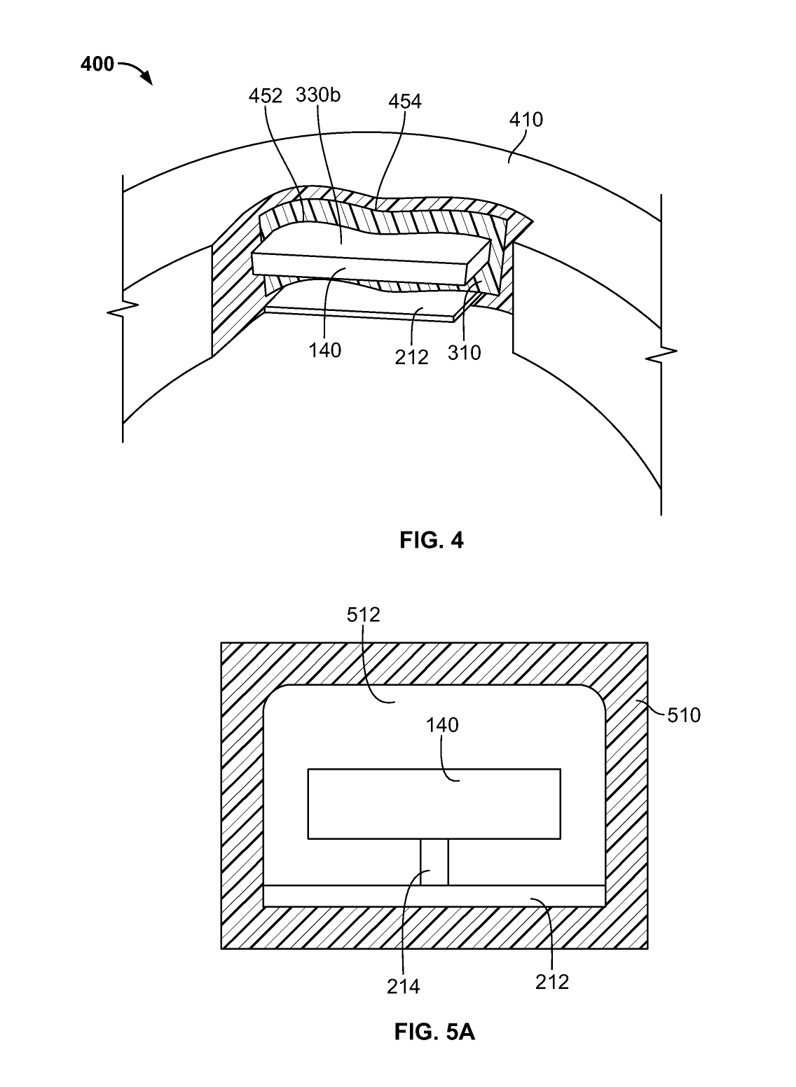

FIG. 4 schematically depicts an overmolded structure 400. In particular, FIG. 4 depicts a cutaway view of battery 140 with an epoxy covering 310, and connected to a flexible printed circuit 212. The overmolding material 410, e.g., a thermoplastic elastomer (TPE) structure, represents a second stage of the battery overmolding process, wherein overmolding material 410 has been overmolded around battery 140 such that battery 140 is functional after the overmolding process. In one implementation, overmolded structure 400 comprises battery 140 with an outer surface 330b. Outer surface 330b of battery 140 may be in contact with an inner surface 452 of covering 310. Additionally, an outer surface of the covering 310 may contact an inner surface of overmolding material 410 at an interface 454.

It is known that a lithium polymer pillow pack battery 140, among other battery types and configurations, may expand, or “swell,” during operation. Advantageously, the epoxy covering 310 results in battery 140 being fully functional within structure 400, and without being adversely affected by battery expansion, or swell during charging and discharging.

Further advantageously, structure 400 may allow for space savings, and improved tolerance specification in, among others, the device 100. In this way, because covering 310 conforms exactly, or substantially exactly, to the shape of battery 140, a tolerance range associated with the dimensions of an inner cavity within the covering 310 to accommodate battery 140 is not required. In contrast, if a pre-formed structure is used to encapsulate battery 140, this pre-formed structure will have a tolerance range associated with an inner cavity that is to accommodate/encapsulate battery 140, and/or battery 140 will have a tolerance range for fitting within the inner cavity. The elimination of one or more tolerance ranges reduces the total aggregate tolerance of the entire assembly in which the battery 140 is utilized (e.g. device 100). This reduction in aggregate tolerance permits closer fitting in devices with tight space constraints.

For example, battery 140 may comprise a first width measuring 5.0 mm+/−0.5 mm. In one implementation, a pre-formed structure may be used to encapsulate the battery 140. Accordingly, the pre-formed structure may comprise an inner width corresponding to the first width of battery 140, and measuring 6.0 mm±0.5 mm. These tolerance ranges ensure that at their extreme values, e.g. when the first width measures 5.5 mm, and the inner width measures 5.5 mm, battery 140 will still fit within the pre-solidified structure. Continuing this example, the pre-formed structure may be designed to have a thickness of at least 2 mm. This thickness corresponds to an outer width measuring 11.0 mm±0.5 mm. In this way, at their extreme values of 6.5 mm and 10.5 mm, the pre-solidified structure thickness is at least 2 mm (2 mm on either side of battery 140 giving 4 mm total thickness). In contrast, using coating 310 as described above may achieve desired protection of battery 140 using less space within device 100, by eliminating at least the tolerance range associated with the inner width of the pre-formed structure. Specifically, for the exemplary same battery 140 with a first width measuring 5.0 mm±0.5 mm, it may be desirable to have coating 310 with a thickness of at least 2 mm. Due to the fact that the epoxy 310, before solidification, conforms exactly, or substantially exactly, to the shape of battery 140, no tolerance range associated with an inner width of the cavity that is to accommodate battery 140 needs to be specified. Accordingly, an outer width of epoxy coating 310, corresponding to the first width of battery 140, may measure 10.0 mm±0.5 mm. In this way, at their extreme values of 5.5 mm and 9.5 mm, the thickness of epoxy coating 310 will measure at least 2 mm on either side of battery 140. In this example, the epoxy coating 310 reduces the overall width requirement by 1.0 mm (11 mm outer width of pre-solidified structure versus 10 mm outer width of epoxy coating 310). This technique, when used on battery 140 alone, or in combination with other components, may represent significant space savings within a portable electronic device, such as device 100 from FIG. 1. Tolerance “stackup,” (otherwise referred to as “tolerance stacks”) refers to the cumulative or aggregate nature of dimensional tolerance ranges. In other words, for a given device, such as device 100, the space required to accommodate the constituent components, such as components 110a-110c, 120, 130, and 140, of the device increases with the number of tolerance ranges associated with each of the one or more constituent components. Accordingly, coating 310 reduces space requirements by removing one or more tolerance ranges from a group of tolerance ranges associated with the constituent components of a device, such as components 110a-110c, 120, 130, and 140 of device 100.

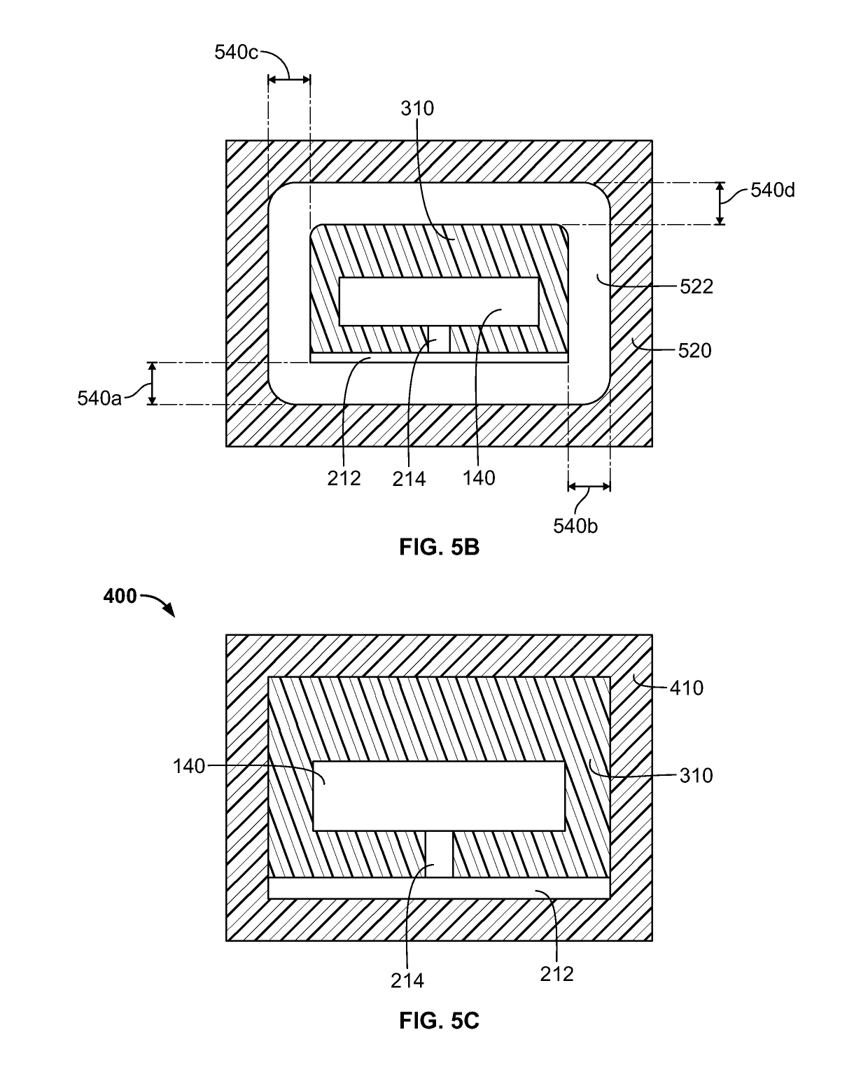

FIGS. 5A-5C schematically depict cross-sectional diagrams of multiple stages of a battery overmolding process. In particular, FIG. 5A schematically depicts a cross-sectional view of an exemplary first stage of a battery overmolding process. FIG. 5A includes battery 140 connected to flexible printed circuit 212 by wired connection 214. In preparation for encapsulation of battery 140 in an epoxy coating 310, components 140, 212, and 214 are held within a first mold 510. The first mold 510 forms a first cavity 512 around components 140, 212, and 214 that will be filled with an un-solidified epoxy resin. One of ordinary skill will recognize that the first mold 510 may be constructed from any material suitable for forming an un-solidified epoxy resin into a predetermined shape with predetermined dimensions. In this way, the first mold 510 may be constructed from, among others, a metal or alloy, a polymeric material, a ceramic, or a fiber reinforced material, or combinations thereof. Furthermore, in one implementation, the first mold 510 may be coated, temporarily or permanently, with a release agent/material such that the first mold 510 may not adhere to a solidified epoxy coating 310 prior to removal of the first mold 510. The first mold 510 may also include a mechanical system for release or removal of the first mold 510 from a solidified epoxy coating 310 formed within the first cavity 512. The first mold 510 may be configured with one or more openings (not shown) through which un-solidified epoxy resin is introduced into the first cavity 512 in flowable form. The flowable epoxy resin may then solidify (e.g., by curing) in the mold 510 to form coating 310. It is understood that this process for forming covering 310 may be used with other coating materials in flowable form.

FIG. 5B schematically depicts a cross-sectional view of an exemplary second stage of a battery overmolding process. In particular, FIG. 5B depicts the battery 140 connected to the flexible printed circuit 212 by wired connection 214, wherein the battery 140 is coated by an epoxy coating 310. Additionally, FIG. 5B depicts a second mold 510 which forms a second cavity 522. The second cavity 522 represents a space to be filled with, in one implementation, an overmolding material, e.g., a thermoplastic elastomer. In this way, the second mold 520 may be formed by any material with mechanical properties that can withstand the temperatures and pressures associated with an overmolding process. In another implementation, the second mold 520 may be formed by one or more components of an injection molding device (not shown).

In one implementation, components 140, 212, 214, and 310 may be held within the second mold 520 by one or more spacer, or standoff elements (not shown). Various implementations of spacer, or standoff elements will be readily understood to those of skill in the art, and in one embodiment, a portion of a frame of the device 100 may be used as such a spacer or standoff element. In this way, the second cavity 522 may extend around all of the components 140, 212, 214, and 310, and such that the inner walls of the second mold 520 are spaced apart from the components by distances 540a-540d. In one implementation, distances 540a-540d may each measure at least 0.25 mm (0.25 mm at a minimum). In another implementation, distances 540a-540d may each measure 0.25 mm on average. In yet another implementation, distances 540a-540d may each measure at least 0.5 mm, or 0.5 mm on average, or at least 1.0 mm, or 1.0 mm on average. In yet another implementation, distances 540a-540d may be equal to one another, or one or more of distances 540a-540d may differ from one another. Furthermore, and while not depicted in FIG. 5B, it will be readily understood to those of skill that the second mold 520 may include one or more openings through which a flowable substance (TPE) may be injected in order to overmold the battery 140.

FIG. 5C schematically depicts a cross-sectional view of an exemplary third stage of a battery overmolding process. In particular, FIG. 5C depicts battery 140 connected to flexible printed circuit 212 by connection 214. Battery 140 is surrounded by coating 310, wherein said coating 310 also partially covers the flexible printed circuit 212. In this way, the coating 310 depicted in FIG. 5C may partially protect the flexible printed circuit 212 from the high temperatures and pressures used during an overmolding process. Furthermore, battery 140 has been overmolded with the overmolding material 410, which has been injected into the second cavity 522 to form an overmolded structure 400 similar to that depicted in FIG. 4.

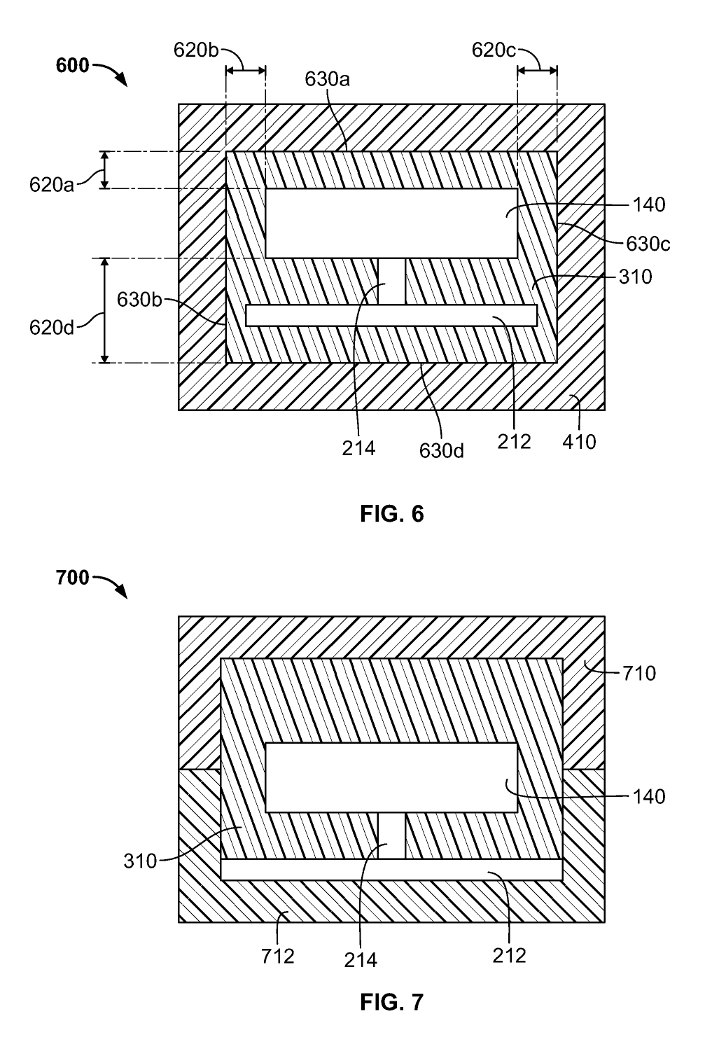

FIG. 6 schematically depicts a cross-sectional view of another embodiment of an overmolded battery structure 600. In particular, structure 600 includes the battery 140 connected to the flexible printed circuit 212 by connection 214. In this embodiment, components 140, 212, and 214 are wholly coated by covering 310. It is noted that components 140, 212, and 214 may be held within a mold structure (not shown in FIG. 6) similar to that depicted in FIG. 5A, using one or more spacer, or standoff elements. Various implementations of spacer/standoff elements that may be employed to arrive at structure 600 will be readily apparent to those of skill in the art.

In one implementation, the dimensions of the covering 310 may be such that a thickness (620a-620d) of the covering 310 between battery 140 and a surface (630a-630d) of overmolding material 410 is at least 0.25 mm. In another implementation, however, thicknesses 620a-620d are at least 0.5 mm, or at least 1.0 mm. In one exemplary implementation, thicknesses 620a-620d may each measure at least 0.25 mm. In another exemplary implementation, thicknesses 620a-620d may each measure at least 0.5 mm, or at least 1.0 mm. In another implementation, thicknesses 620a-620d may be equal to one another, or one or more of thicknesses 620a-620d may differ from one another.

FIG. 7 schematically depicts a cross-sectional view of another embodiment of an overmolded battery structure 700. In particular, FIG. 7 depicts a “multi-shot” overmolded battery 140. Similar to FIGS. 5A-5C, and FIG. 6, FIG. 7 depicts the battery 140 connected to the flexible printed circuit 212 by connection 214. FIG. 7 further depicts components 140, 212, 214 with an epoxy covering 310. In one implementation, a battery 140 may be may be overmolded using a “multi-shot” overmolding process, wherein a “multi-shot” overmolding process molds, among others, one or more flowable materials, such as TPE, over one or more components as multiple discrete molding steps. In this way, structure 700 is embodied with a “first shot,” to form a first overmolding material 710, and a “second shot,” to form a second overmolding material 712 that may be different from first overmolding material 710, where both the first and second overmolding materials 710, 712 form portions of structure 700. In one embodiment, the first overmolding material 710 may be formed prior to the covered battery 140 being introduced into the mold cavity, and may provide a structure for supporting the battery 140 during the second or any subsequent shots of the overmolding process. Additional “shots” may be used consecutively to form further portions of the structure 700. Multi-shot overmolding processes may be carried out using injection molding equipment with two or more barrels, which allow two or more materials to be shot into a same mold during a same molding cycle.

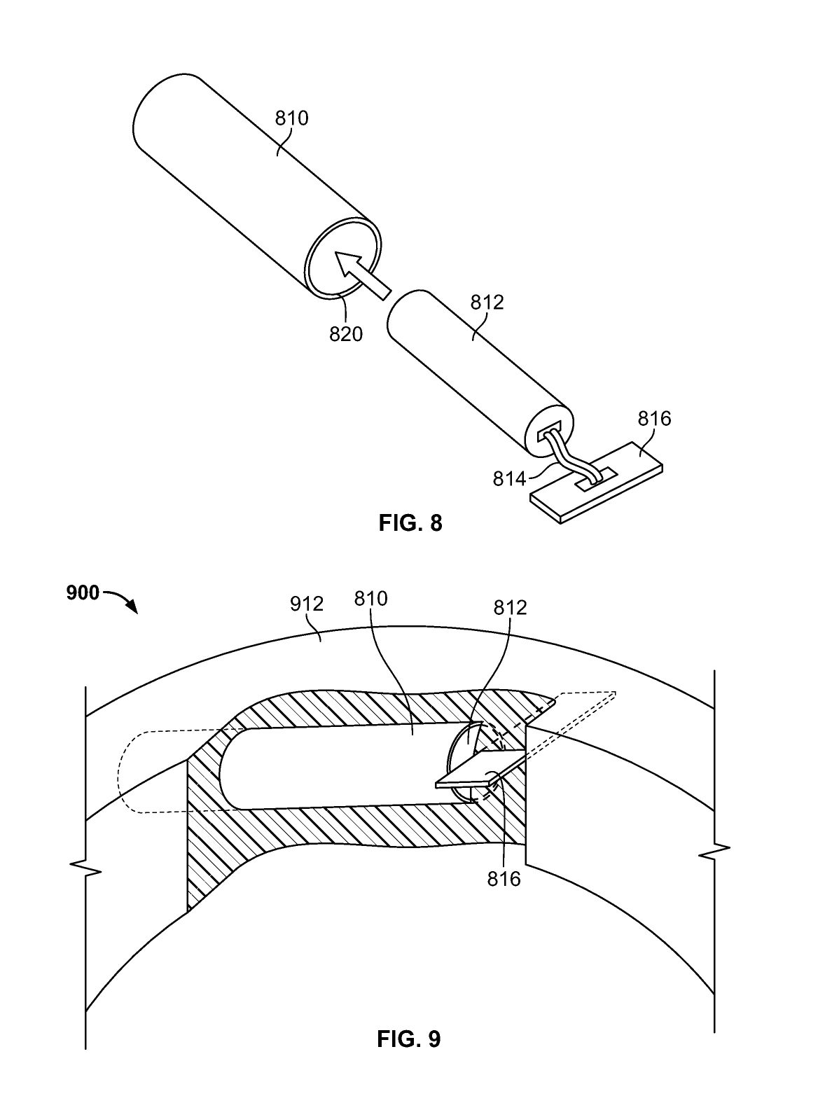

FIG. 8 schematically depicts another embodiment of a structure for protection of a battery during an overmolding process. In particular, FIG. 8 depicts a battery 812 connectable to a flexible printed circuit 816 by a wired connection 814. Battery 812 is depicted with a substantially cylindrical, however battery 812 may be a lithium polymer pillow pack battery similar to battery 140 from FIG. 2, or may have a different shape, in other embodiments. Battery 812 may additionally or alternately be embodied with alternative battery chemistries, such as alkaline, nickel cadmium, and nickel metal hydride configurations, in some embodiments. Additionally, wired connection 814 and flexible printed circuit 816 may be similar to wired connection 212 and flexible printed circuit 212, respectively, from FIG. 2. Similar to battery 140, it may be desirable to overmold battery 812 to achieve one or more design objectives associated with the design of a portable electronic device, such as athletic performance monitoring device 100 from FIG. 1.

In one implementation, battery 812 may be overmolded using a pre-formed protective casing 810. Protective casing 810 may be configured to withstand the high temperatures and high pressures associated with an overmolding process. Accordingly, protective casing 810 may be constructed from any suitable material with mechanical properties capable of withstanding overmolding conditions, including temperatures of 220° C. or greater, and pressures ranging from 20 MPa to 35 MPa or greater. In one implementation, protective casing 810 may be constructed from a stainless steel material, however one of ordinary skill will recognize that protective casing 810 may be constructed using other materials, such as, among others, other metals, alloys, polymeric materials, ceramics, or fiber-reinforced materials, or combinations thereof. In one implementation, battery 812 is inserted into protective casing 810 through a first opening 820, prior to an overmolding process. Casing 810 may also include a cap (not shown) to cover the opening and resist ingress of flowable materials during overmolding. Further, the casing 810 may include a passage that accommodates wired connections 814 (e.g., through the cap), which may be sealed with a potting compound or other sealant.

FIG. 9 schematically depicts an overmolded structure 900 that includes a battery 812 and casing 810 as illustrated in FIG. 8. In particular, FIG. 9 depicts a cutaway view of a battery 812 overmolded with an overmolding material 912, e.g. a thermoplastic elastomer (TPE) structure, wherein battery 812 is protected from the high temperatures and high pressures associated with an overmolding process by protective casing 810. In one embodiment, and as depicted in FIG. 9, flexible printed circuit 816 is not covered during an overmolding process. In this way, flexible printed circuit 816 is directly overmolded with the TPE structure 912. In another implementation, flexible printed circuit 816 may be encapsulated within protective cover 810 prior to an overmolding process. In a further implementation, flexible printed circuit 816 may be connected to battery 812 subsequent to the overmolding process.

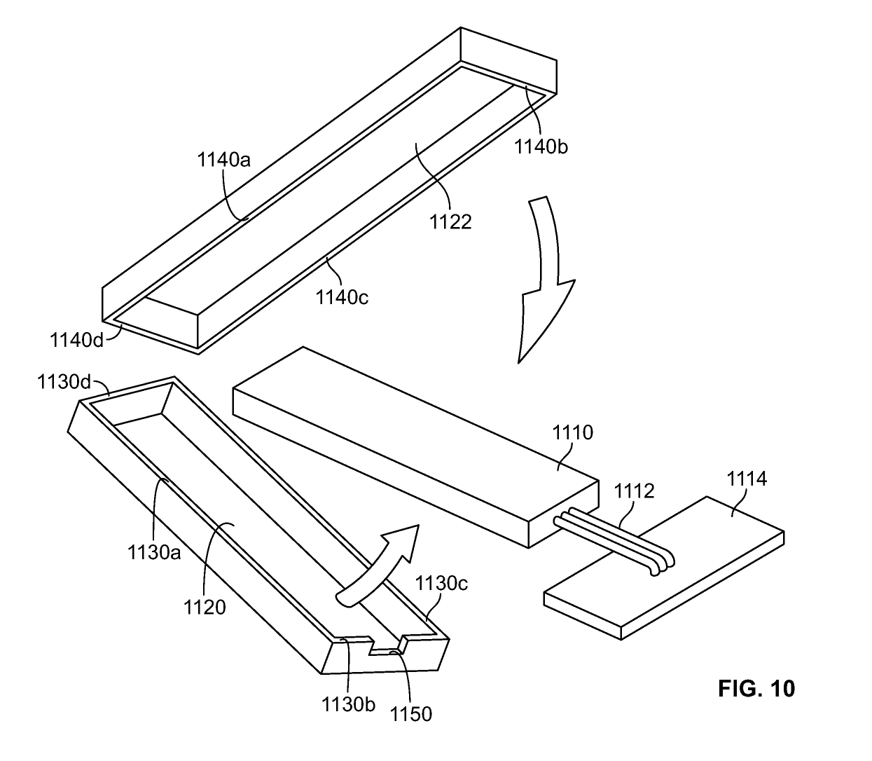

FIG. 10 schematically depicts another embodiment of a structure for protection of a battery during an overmolding process. In particular, FIG. 10 depicts a battery 1110 connected to a flexible printed circuit 1114 by a wired connection 1112. Battery 1110 may be a lithium polymer pillow pack battery similar to battery 140 from FIG. 2, and may also have a structure that is substantially rectangular (cuboidal). In another embodiment, battery 1110 may have a different form, structure, function, etc. In this embodiment, battery 1110 may be protected from the high temperatures and high pressures associated with an overmolding process by a protective cover, wherein the protective cover is embodied with a clamshell design including a first section 1120, and a second section 1122. The first section 1120, and the second section 1122 may encapsulate battery 1110 by coupling surfaces 1130a-1130d with surfaces 1140a-1140d, respectively. The coupling between surfaces 1130a-1130d and surfaces 1140a-1140d may use any conventional alignment aids known to one of ordinary skill, such as alignment tabs or pins (not shown), and the like. Furthermore, each of the first section 1120, and the second section 1122 of the protective cover may be constructed using any suitable material with mechanical properties to resist the temperatures and pressures associated with an overmolding process, such as, among others, a metal, an alloy, a ceramic, a fiber-reinforced material, or a polymer, or combinations thereof. In one implementation, the first section 1120 and the second section 1122 of the protective cover may encapsulate battery 1110 to facilitate overmolding of an overmolding material similar to the overmolding material 912 described above with respect to FIG. 9. In one embodiment, the first section 1120 has a first opening 1150 to connect the battery 1110 to the flexible printed circuit 1114 by the wired connection 1112. The first opening 1150 may include a sealant, such as a potting compound, to resist ingress of a flowable substance during overmolding.

It will be readily apparent to those of skill in the art that alternative embodiments of the first section 1120, and second section 1122 may be used to protect battery 1110, without departing from the scope of the disclose described herein. Accordingly, the first section 1120 and second section 1122 may alternatively form a protective cover that is substantially cylindrical in shape, or substantially a cube shape, and the like.

While the invention has been described with respect to specific examples including presently preferred modes of carrying out the invention, those skilled in the art will appreciate that there are numerous variations and permutations of the above described systems and methods. Thus, the spirit and scope of the invention should be construed broadly as set forth in the appended claims.

What is claimed is:

1. An athletic performance monitoring device comprising:
a structural frame for the device;
an electronic component supported by the structural frame and configured for at least one of collecting performance data and displaying information to a user;
a thermoplastic overmolded material connected to and supported by the structural frame, the overmolded material forming at least a portion of an outer casing structure of the device and at least partially encasing the electronic component;
a battery connected to the electronic component and configured for supplying power to the electronic component; and
an epoxy layer at least partially surrounding the battery, the epoxy layer having an inner epoxy layer surface and an outer epoxy layer surface, wherein the inner epoxy layer surface is configured to contact an outer surface of the battery, and the outer epoxy layer surface at least partially surrounded by and contacted by the overmolded material, and wherein the epoxy layer is configured to resist transmission of temperature and pressure to the battery during an overmolding process.

2. The athletic performance monitoring device of claim 1, wherein the overmolded material comprises one or more materials selected from a group consisting of: a thermoplastic elastomer, a thermoplastic polyurethane, a silicone material, a nylon material, an acetal material, or a polycarbonate material.

3. The athletic performance monitoring device of claim 1, wherein the epoxy layer has a minimum thickness of at least 0.25 mm.

4. The athletic performance monitoring device of claim 1, wherein the epoxy layer has a minimum thickness of at least 0.5 mm.

5. The athletic performance monitoring device of claim 1, wherein the battery is a lithium polymer battery.

6. The athletic performance monitoring device of claim 1, wherein outer casing structure of the device has a curved contour, and wherein the battery and the epoxy layer have curved contours to match the curved contour of the outer casing structure.

7. A battery assembly, comprising:
a battery;
a wired connection connected to the battery and extending from the battery; and
a polymer coating at least partially surrounding the battery, such that an inner surface of the polymer coating covers and contacts a majority of an outer surface of the battery,
wherein the wired connection extends through the polymer coating, such that the wired connection is accessible and connectable to an electronic component from an exterior of the polymer coating, and
wherein the polymer coating is configured to resist transmission of temperature and pressure to the battery during an overmolding process.

8. The battery assembly of claim 7, wherein the polymer coating is epoxy.

9. The battery assembly of claim 7, further comprising a flexible printed circuit engaged with an outer surface of the polymer coating, wherein the wired connection is connected to the flexible printed circuit, such that the battery is configured for supplying power to the flexible printed circuit.

10. The battery assembly of claim 7, wherein the polymer coating has a minimum thickness of at least 0.25 mm.

11. The battery assembly of claim 7, wherein the polymer coating has a minimum thickness of at least 0.5 mm.

12. A method comprising:
coating at least a portion of an outer surface of a battery with an epoxy resin;
curing the epoxy resin to form an epoxy layer at least partially surrounding the battery, with an inner surface in contact with the outer surface of the battery, to form a coated battery assembly; and
injection molding a flowable material around at least a portion of the coated battery assembly, wherein the epoxy layer resists transmission of temperature and pressure of the injection molding to the outer surface of the battery, wherein the flowable material solidifies to form an overmolded material at least partially surrounding the coated battery assembly.

13. The method of claim 12, wherein the flowable material is a thermoplastic elastomer.

14. The method of claim 12, wherein the battery has a wired connection extending from the battery and configured for connection to an electronic component, and wherein the wired connection is accessible through the epoxy layer.

15. The method of claim 14, wherein the wired connection is connected to the electronic component, and the electronic component is positioned outside the epoxy layer, and wherein the flowable material is further injection molded around at least a portion of the electronic component.

16. The method of claim 12, wherein the epoxy layer has a minimum thickness of at least 0.25 mm.

17. The method of claim 12, wherein the epoxy layer has a minimum thickness of at least 0.5 mm.

18. An overmolded assembly, comprising:
an electronic circuit;
a battery connected to the electronic circuit and configured for supplying power to the electronic circuit;
an epoxy coating, at least partially coating the battery, wherein the epoxy coating is configured to resist transmission of temperature and pressure to the battery during an overmolding process, wherein the epoxy coating has an inner surface and an outer surface, and wherein the inner surface at least partially coats the electronic circuit; and
an overmolded thermoplastic elastomer layer at least partially surrounding the electronic circuit and the battery, wherein the outer surface of the epoxy coating is at least partially surrounded by and contacted by the overmolded thermoplastic elastomer layer.

19. The overmolded assembly of claim 18, wherein the epoxy coating has a thickness of at least 1.0 mm.

20. The overmolded assembly of claim 18, wherein the epoxy coating reduces transmission of temperature and pressure associated with injection molding of the overmolded thermoplastic elastomer layer by at least 40% to the outer surface of the electronic circuit.
